(19) United States
(12) Patent Application Publication
(10) Pub. No.: US 2026/0352205 A1
(43) Pub. Date: Nov. 5, 2026

(54) GATE DRIVE CIRCUIT

(71) Applicant: MITSUBISHI ELECTRIC CORPORATION, Tokyo (JP)

(72) Inventor: Yukihiko WADA, Chiyoda-ku, Tokyo (JP)

(73) Assignee: MITSUBISHI ELECTRIC CORPORATION, Tokyo (JP)

(21) Appl. No.: 19/475,775

(22) PCT Filed: Apr. 25, 2023
(86) PCT No.: PCT/JP2023/016266

§ 371 Date: Oct. 16, 2025

(51) Int. Cl. H03K 17/284

(52) U.S. Cl. CPC H03K 17/284

(57) ABSTRACT

In a gate drive circuit, a first switch turns a driven element into an ON state when a gate drive signal has a first logical value. A second switch turns the driven element into an OFF state when the gate drive signal has a second logical value. A diode is connected between the second switch and a reference node. A capacitor has a first electrode connected to a connection node between the second switch and the diode. The capacitor has a second electrode to which a reference potential is applied after the gate drive signal switches from the first logical value to the second logical value and charges in a gate terminal of the driven element are subsequently discharged, and to which a positive potential is applied before the gate drive signal switches from the second logical value to the first logical value.

### TECHNICAL FIELD

The present disclosure relates to a gate drive circuit and is used, for example, for a gate drive circuit that drives a power semiconductor device.

BACKGROUND ART There are several types of power semiconductor devices such as a metal-oxide-semiconductor field-effect transistor (MOSFET) and an insulated gate bipolar transistor (IGBT). These power semiconductor devices are applied to a semiconductor apparatus such as an inverter. In an inverter, a plurality of power semiconductor devices connected in series are used. Most simply, two power semiconductor devices connected in series are alternately turned on and off to raise or lower the potential at a point of connection between these power semiconductor devices.

In order to turn on the power semiconductor device, a positive voltage is applied to a gate terminal of the power semiconductor device. In order to turn off the power semiconductor device, a zero voltage or a negative voltage is applied to the gate terminal of the power semiconductor device. A gate drive circuit serves to apply these voltages to the power semiconductor device, i.e., a driven element.

Each of the power semiconductor devices connected in series is referred to as an arm. The arms connected on the upper and lower sides are controlled to be alternately turned on, i.e., such that the arms are not simultaneously in an ON state, and more specifically, such that one of the arms is in an OFF state when the other of the arms is in an ON state. Focusing on one of the arms, only when this one arm (hereinafter referred to as a self-arm) is in an OFF state, the other arm (hereinafter referred to as a counter arm) is in an ON state. The moment at which the power semiconductor device is turned on is referred to as “turn-on”, and the moment at which the power semiconductor device is turned off is referred to as “turn-off”.

If the upper and lower arms are simultaneously turned on, the power supply voltage is short-circuited through both of the arms. In this case, a high current may flow through both of the arms, and the power semiconductor device may be destroyed due to heat generation.

When the counter arm is turned on while the self-arm is in an OFF state, the voltage at the point of connection between the upper and lower arms abruptly changes, so that a voltage is rapidly applied to the power semiconductor device of the self-arm. For example, in the case of a MOSFET, a voltage is rapidly applied between a drain terminal and a source terminal. This is due to the operation of the counter arm, and the self-arm needs to be remained in an OFF state also at this moment.

In general, rapidly applying a voltage to a power semiconductor device causes a phenomenon in which the voltage at the gate terminal is raised. For example, in the case of a MOSFET, a current that charges a parasitic capacitance between a drain terminal and a gate terminal flows from the drain terminal toward the gate terminal, and then, the current flows through a resistor (a gate resistor) connected to the gate terminal. This results in occurrence of a potential difference across the gate resistor, and the potential at the gate terminal rises.

If the gate drive device has a poor ability to keep the potential of the gate terminal at a low voltage, the gate voltage rises too high at this time and exceeds the gate voltage (a gate threshold voltage) necessary for turning on the power semiconductor device. As a result, both of the power semiconductor devices of the self-arm and the counter arm are turned on, which may cause a short circuit in a power supply and may result in destruction of the power semiconductor devices.

The phenomenon in which the self-arm is erroneously turned on when the counter arm is turned on is called a false turn-on phenomenon. A method applicable for preventing such a false turn-on phenomenon is a method of decreasing the resistance value of the gate resistor, increasing the apparent gate capacitance by installing an additional capacitance between the gate terminal and the source terminal, or applying a negative voltage to the gate terminal. However, when the resistance value of the gate resistor is reduced, the switching speed may increase, and electromagnetic noise may increase. When the gate capacitance is increased, the load on the gate drive circuit increases, and heat generation in the gate drive circuit also increases.

Thus, a method of setting a gate voltage to be negative during OFF time, i.e., applying a negative bias, is generally used. In order to apply a negative bias, a negative power supply is generally required. However, since another power supply is required in addition to a positive power supply for turning on the gate, this method using a negative power supply may cause an increase in circuit scale and an increase in cost. In order to avoid these problems, a method of generating a negative bias using only a positive power supply has been known.

For example, in a drive circuit disclosed in FIG. 2 in Japanese Patent Laying-Open No. 2004-159424 (PTL 1), a capacitor for negative bias generation is provided. This capacitor is charged in advance when a MOSFET as a driven element is in an ON state, and is connected in reverse polarity between a gate terminal and a source terminal of the driven element when the driven element is turned off.

Japanese Patent Laying-Open No. 2013-201883 (PTL 2) also discloses a negative bias generation circuit similar to that in the above-mentioned PTL 1. In particular, in a drive circuit in FIG. 20 in this literature, a capacitor for negative bias generation as described above is connected between a gate terminal and a source terminal of a MOSFET only during a certain time period since the MOSFET is turned off.

### CITATION LIST

### Patent Literature

PTL 1: Japanese Patent Laying-Open No. 2004-159424
PTL 2: Japanese Patent Laying-Open No. 2013-201883

### SUMMARY OF INVENTION

### Technical Problem

In the above-described prior art, since the connection of the capacitor is switched at the time of turn-off, the negative charges accumulated in one of electrodes of the capacitor is canceled out by the positive charges accumulated in the gate terminal of the driven element. This causes a problem that a negative bias cannot be sufficiently applied to the gate terminal of the driven element. This problem becomes particularly remarkable when the gate capacitance of the driven element is large. If the capacitance of the capacitor for negative bias generation is further increased, the influence caused by cancellation of the charges can be suppressed, but the circuit scale and the cost may be increased.

The present disclosure has been made in order to solve the above-described problems, and an object thereof is to provide a gate drive circuit in which a necessary negative bias can be applied to a gate by a capacitor having a minimum capacitance.

### Solution to Problem

In one embodiment, a gate drive circuit to drive a driven element based on a gate drive signal is provided. The gate drive circuit includes a first switch, a second switch, a diode, a capacitor, a potential switching circuit, and a signal generation circuit. The first switch is connected between a power supply node to which a positive potential is applied and a gate terminal of the driven element to turn the driven element into an ON state by being rendered conductive when the gate drive signal has a first logical value. The second switch is connected between a reference node to which a reference potential is applied and the gate terminal of the driven element to turn the driven element into an OFF state by being rendered conductive when the gate drive signal has a second logical value. The diode is connected between the second switch and the reference node such that the reference node is located on a cathode side. The capacitor has a first electrode connected to a connection node between the second switch and the diode. The potential switching circuit applies the reference potential to a second electrode of the capacitor when the control signal is enabled, and applies the positive potential to the second electrode of the capacitor when the control signal is disabled. The signal generation circuit generates the control signal based on the gate drive signal. The signal generation circuit enables the control signal after the gate drive signal switches from the first logical value to the second logical value and charges in the gate terminal of the driven element are subsequently discharged, and disables the control signal before the gate drive signal switches from the second logical value to the first logical value.

### Advantageous Effects of Invention

According to the gate drive circuit in the above-described embodiment, the control signal for enabling a negative bias is enabled after the gate drive signal switches from the first logical value to the second logical value and the charges in the gate terminal of the driven element are subsequently discharged, and the control signal is disabled before the gate drive signal switches from the second logical value to the first logical value. This makes it possible to provide a gate drive circuit in which a necessary negative bias can be applied to a gate by a capacitor having a minimum capacitance.

### BRIEF DESCRIPTION OF DRAWINGS

FIG. 1 is a circuit diagram showing a configuration example of a gate drive circuit according to a first embodiment.

FIG. 2 is a timing chart showing an operation of the gate drive circuit in FIG. 1.

FIG. 3 is a schematic circuit diagram conceptually showing a charging status of a capacitor and a charging status of a gate capacitance immediately after a second electrode of the capacitor is connected to a reference potential.

FIG. 4 is a diagram showing a temporal change in an actual gate voltage after a driven element is turned off.

FIG. 5 is a timing chart showing the operation of the gate drive circuit in FIG. 1 when an ON-pulse width of a gate drive signal is very short.

FIG. 6 is a timing chart showing an operation of a modification of the gate drive circuit in FIG. 1.

FIG. 7 is a circuit diagram showing a configuration example of a gate drive circuit according to a second embodiment.

FIG. 8 is a timing chart showing an operation of the gate drive circuit in FIG. 7.

FIG. 9 is a circuit diagram showing a configuration example of a gate drive circuit in a third embodiment.

FIG. 10 is a circuit diagram showing a configuration example of a gate drive circuit in a fourth embodiment.

### DESCRIPTION OF EMBODIMENTS

Hereinafter, each embodiment will be described in detail with reference to the accompanying drawings. The same or corresponding portions are denoted by the same reference characters, and the description thereof will not be repeated.

### First Embodiment

### Configuration of Gate Drive Circuit

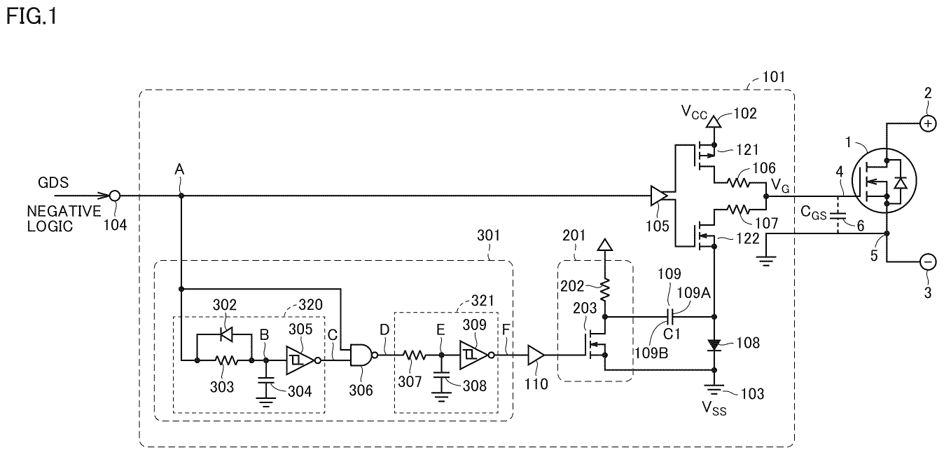

FIG. 1 is a circuit diagram showing a configuration example of a gate drive circuit according to the first embodiment. In FIG. 1, a driven element 1 is a MOSFET.

Driven element 1 has a drain terminal 2 as a first main terminal, a source terminal 3 as a second main terminal, and a gate terminal 4 as a control terminal. The main current flowing between the first and second main terminals is controlled to be ON and OFF by the gate voltage applied to gate terminal 4. In the example in FIG. 1, driven element 1 further has a source reference terminal 5 between a source electrode and source terminal 3 in order to obtain a source potential.

A parasitic gate capacitance 6 exists between a gate and a source of driven element 1. Although the gate capacitance does not exist as a component, it is virtually shown by a dotted line in FIG. 1 as if the component is connected.

Gate drive circuit 101 is connected to gate terminal 4 and source terminal 3 of driven element 1. In the example in FIG. 1, gate drive circuit 101 is connected not to source terminal 3 but to source reference terminal 5 provided between source terminal 3 and the source electrode of driven element 1. Gate drive circuit 101 includes: a power supply node 102 to which a positive potential V_{CC} by a positive power supply is applied; and a reference node 103 to which a reference potential V_{SS} is applied. Reference potential V_{SS} is equal to the potential at source reference terminal 5.

Gate drive circuit 101 is driven by a gate drive signal GDS that has been input to a signal input terminal 104. Gate drive circuit 101 has a mechanism for switching, according to the input gate drive signal GDS, whether to connect gate terminal 4 of driven element 1 to the positive potential side or to the reference potential side.

Specifically, in the example in FIG. 1, gate drive circuit 101 includes a gate resistor 106 and a switch 121 (the first switch) for turn-on that are connected in series between gate terminal 4 and power supply node 102 in order to switch gate terminal 4 to the positive potential side. Gate drive circuit 101 further includes a gate resistor 107 and a switch 122 (the second switch) for turn-off that are connected in series between gate terminal 4 and reference node 103 in order to connect gate terminal 4 to the reference potential side. In the example in FIG. 1, switch 121 is a P-channel MOSFET, and switch 122 is an N-channel MOSFET. Gate resistor 106 is connected to be closer to gate terminal 4 than switch 121 is to gate terminal 4, and gate resistor 107 is connected to be closer to gate terminal 4 than switch 122 is to gate terminal 4.

Further, gate drive circuit 101 includes a non-inverting buffer 105 for driving the gate terminal of switch 121 and the gate terminal of switch 122 in response to gate drive signal GDS. Gate drive signal GDS input to signal input terminal 104 is input to non-inverting buffer 105.

Further, gate drive circuit 101 includes a diode 108, a capacitor 109, a potential switching circuit 201, a non-inverting buffer 110, and a signal generation circuit 301 as a mechanism for inputting a negative potential to gate terminal 4 of driven element 1.

Diode 108 is connected between switch 122 and reference node 103 such that an anode of diode 108 is located on the switch 122 side and a cathode of diode 108 is located on the reference node 103 side.

Capacitor 109 has a first electrode 109A connected to a point of connection between switch 122 and diode 108. Capacitor 109 has a second electrode 109B connected to potential switching circuit 201.

Potential switching circuit 201 includes a pull-up resistor 202 and a switch 203 (the third switch). In the present example, switch 203 is an N-channel MOSFET. Pull-up resistor 202 has the first end connected to power supply node 102 and the second end connected to both second electrode 109B of capacitor 109 and a drain terminal of switch 203. Switch 203 has a source terminal connected to reference node 103. Switch 203 has a gate terminal that is driven by non-inverting buffer 110.

Signal generation circuit 301 receives, as an input, the gate drive signal having been input to signal input terminal 104 and outputs a control signal for driving non-inverting buffer 110. When a high-level control signal is output from signal generation circuit 301 to non-inverting buffer 110, switch 203 is turned on to thereby enable the negative bias at gate terminal 4 of driven element 1. When a low-level control signal is output from signal generation circuit 301 to non-inverting buffer 110, switch 203 is turned off to thereby disable the negative bias at gate terminal 4 of driven element 1. In the above-described case, a high-level control signal is referred to as an enabled control signal, and a low-level control signal is also referred to as a disabled control signal.

Signal generation circuit 301 includes a first delay circuit 320, a logical operation circuit 306, and a second delay circuit 321.

Gate drive signal GDS of a negative logic is input to first delay circuit 320. First delay circuit 320 generates a first delay signal by delaying a turn-off edge (i.e., a rising edge) of the input gate drive signal GDS of a negative logic without delaying a turn-on edge (i.e., a falling edge) thereof. Further, first delay circuit 320 outputs a signal obtained by inverting the logical value of the first delay signal.

More specifically, as shown in FIG. 1, first delay circuit 320 includes: a low-pass filter (also referred to as an RC filter) constituted of a resistor 303 and a capacitor 304; a diode 302; and a Schmitt trigger inverter 305. Resistor 303 and capacitor 304 are connected in this order in series between signal input terminal 104 and reference node 103. Diode 302 is connected in parallel with resistor 303. Diode 302 has an anode terminal connected to a connection node B between resistor 303 and capacitor 304. Thereby, the RC filter functions as a unidirectional RC filter that delays only the rising edge of gate drive signal GDS. The signal that has passed through the RC filter is input to Schmitt trigger inverter 305. Schmitt trigger inverter 305 shapes the input signal and inverts the logical value thereof.

Logical operation circuit 306 computes a logical product of gate drive signal GDS and the inverted signal of the first delay signal output from first delay circuit 320. In the example in FIG. 1, since a NOT-AND (NAND) circuit is used as logical operation circuit 306, logical operation circuit 306 inverts the operation result of the logical product and outputs the inverted result. Note that logical operation circuit 306 may calculate the logical sum of the first delay signal and the inverted signal of gate drive signal GDS, in which case the same logical operation result is obtained.

An output signal from logical operation circuit 306 is input to second delay circuit 321. Second delay circuit 321 delays the output signal from logical operation circuit 306 (i.e., both the rising edge and the falling edge). The delay signal output from second delay circuit 321 is input to non-inverting buffer 110. Thereby, a control signal for controlling potential switching circuit 201 is generated.

More specifically, as shown in FIG. 1, second delay circuit 321 includes: a low-pass filter (also referred to as an RC filter) constituted of a resistor 307 and a capacitor 308; and a Schmitt trigger inverter 309. Resistor 307 and capacitor 308 are connected in this order in series between an output node D of logical operation circuit 306 and reference node 103. The signal that has passed through the RC filter is input to Schmitt trigger inverter 309. Schmitt trigger inverter 309 shapes the input signal and inverts the logical value thereof.

### Operation of Gate Drive Circuit

The following describes the operation of gate drive circuit 101 in FIG. 1, in particular, the operation of signal generation circuit 301.

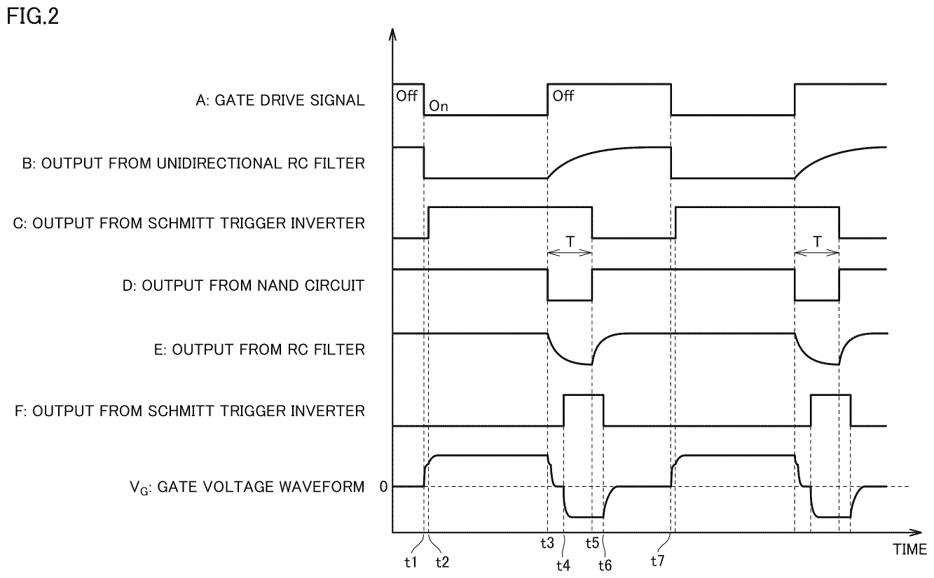

FIG. 2 is a timing chart showing the operation of gate drive circuit 101 in FIG. 1. FIG. 2 shows signal waveforms at nodes A to F in FIG. 1 and a waveform of a gate voltage V_{G} in driven element 1 in FIG. 1. The following is a sequential description thereof.

The signal at node A is gate drive signal GDS and is input through non-inverting buffer 105 to the gate terminal of switch 121 (a P-channel MOSFET) and the gate terminal of switch 122 (an N-channel MOSFET). Switches 121 and 122 constitute a complementary metal-oxide-semiconductor (CMOS).

When gate drive signal GDS is at a high level, switch 122 turns into an ON state to connect gate terminal 4 of driven element 1 to reference node 103. Thereby, driven element 1 turns into an OFF state. On the other hand, when gate drive signal GDS is at a low level, switch 121 turns into an ON state to connect gate terminal 4 of driven element 1 to power supply node 102. Thereby, driven element 1 turns into an ON state. Therefore, gate drive signal GDS is a negative logic.

Time t1 at which gate drive signal GDS switches from a high level to a low level (i.e., the falling edge of gate drive signal GDS) corresponds to a turn-on edge. Time t3 at which gate drive signal GDS switches from a low level to a high level (i.e., the rising edge of gate drive signal GDS) corresponds to a turn-off edge.

The signal at node B indicates the signal output from a unidirectional RC filter of first delay circuit 320 when the signal at node A (i.e., gate drive signal GDS) is input to the unidirectional RC filter.

In general, a low-pass filter constituted of a resistor and a capacitor cuts a high-frequency component of an input signal and allows a low-frequency component of the input signal to pass therethrough. As a result, the signal having passed through the low-pass filter has a shape in which the edge of the input signal is obtuse. However, in the low-pass filter of first delay circuit 320 in FIG. 1, diode 302 is connected in parallel with resistor 303. A cathode of diode 302 is connected to the input side of the low-pass filter and an anode of diode 302 is connected to the output side of the low-pass filter. Thus, when the input signal rises, the diode is disconnected and the low-pass filter is enabled. On the other hand, when the input signal falls, the diode is rendered conductive and the voltage in capacitor 304 rapidly decreases. Thus, the RC filter of first delay circuit 320 functions as a unidirectional filter in which only rising of the input signal is enabled.

Specifically, at time t1 corresponding to the falling edge (i.e., a turn-on edge) of gate drive signal GDS, the output signal from the unidirectional RC filter (i.e., the signal at node B) rapidly falls. On the other hand, at time t3 corresponding to the rising edge (i.e., a turn-off edge) of gate drive signal GDS, the output signal from the unidirectional RC filter (i.e., the signal at node B) gently rises.

The signal at node C indicates the signal output from Schmitt trigger inverter 305 when the signal at node B (i.e., the output signal from the unidirectional RC filter) is input to Schmitt trigger inverter 305.

In general, a Schmitt trigger element refers to an element whose input threshold voltage has hysteresis. However, since Schmitt trigger inverter 305 is used in first delay circuit 320, a signal obtained by inverting the logical value of the input signal is output.

Specifically, in the case where the input signal of Schmitt trigger inverter 305 (i.e., the signal at node B) falls at time t1 in FIG. 2, Schmitt trigger inverter 305 outputs a signal obtained by inverting the input signal after this input signal becomes considerably lower than an intermediate potential. Since the signal at node B abruptly falls at time t1, the output signal from Schmitt trigger inverter 305 rises at time t2 with almost no delay from time t1.

On the other hand, in the case where the input signal of Schmitt trigger inverter 305 (i.e., the signal at node B) rises at time t3, Schmitt trigger inverter 305 outputs a signal obtained by inverting the input signal after this input signal becomes considerably higher than the intermediate potential. Since the signal at node B gently rises at time t3, the output signal from Schmitt trigger inverter 305 falls at time t5 significantly delayed from time t3.

When the waveform in which only the rising of the signal is obtuse as described above is input to Schmitt trigger inverter 305, Schmitt trigger inverter 305 outputs an inverted signal in which only the rising edge of the input signal is significantly delayed.

The signal at node D indicates an output signal from the NAND circuit serving as logical operation circuit 306. As shown in FIG. 1, NAND circuit 306 outputs a signal obtained by inverting the logical product of the signal at node A (i.e., gate drive signal GDS) and the signal at node C (i.e., the output signal from Schmitt trigger inverter 305).

In the case in FIG. 2, the logical product of the signal at node A and the signal at node C is true only during a certain time period T (for example, from time t3 to time t5 in FIG. 2) from the turn-off edge, and is false during other time periods. Thus, the signal at node D (i.e., the output signal from NAND circuit 306) has a reference potential only during certain time period T from the turn-off edge, and has a positive potential during other time periods.

The signal at node E indicates the signal output from the RC filter constituted of resistor 307 and capacitor 308 when the signal at node D is input to this RC filter. Since no diode is connected to resistor 307 of this RC filter, the signal waveform at node D shows a waveform in which both the rising edge and the falling edge are obtuse.

The signal at node F indicates the signal output from Schmitt trigger inverter 309 when the signal at node E (i.e., the output signal from the RC filter) is input to Schmitt trigger inverter 309. As shown in FIG. 2, the signal at node F is a signal obtained by delaying both the rising edge and the falling edge of the signal at node D and then inverting the logical value of this signal. Specifically, the signal at node F switches from a low level to a high level at time t4 at which a prescribed time period has elapsed since the turn-off edge at time t3, and then returns from a high level to a low level at subsequent time t6.

Signal generation circuit 301 inputs the signal at node F, as a control signal for enabling the negative bias, to the gate terminal of switch 203 of potential switching circuit 201 through non-inverting buffer 110. Therefore, in the time period (from time t4 to time t6) during which the signal at node F is at a high level in the time period (from time t3 to time t7) during which gate drive signal GDS is at a high level, switch 203 is rendered conductive. In other time periods, switch 203 is rendered non-conductive.

As described above, first electrode 109A of capacitor 109 is connected to the point of connection between diode 108 and switch 122 for off-driving. Second electrode 109B of capacitor 109 is connected to power supply node 102 via pull-up resistor 202 and connected to reference node 103 via switch 203.

Therefore, in a time period during which switch 203 is non-conductive, a current flows through power supply node 102, pull-up resistor 202, capacitor 109, diode 108, and reference node 103 in this order, and thereby, capacitor 109 is charged such that second electrode 109B thereof is positive and first electrode 109A thereof is negative. On the other hand, in a time period during which switch 203 is rendered conductive, second electrode 109B of capacitor 109 is connected to reference node 103 via switch 203, and thereby, the source terminal of switch 122 that is connected to first electrode 109A of capacitor 109 is biased to a negative potential with respect to reference potential V_{SS} .

Signal generation circuit 301, potential switching circuit 201, and the like are operated as described above to thereby obtain the gate voltage waveform shown in the lowermost stage in FIG. 2.

Specifically, during a time period from the turn-on edge at time t1 to the turn-off edge at time t3 in FIG. 2, switch 121 of gate drive circuit 101 is rendered conductive, so that a positive potential is applied to gate terminal 4 of driven element 1.

During a time period from the turn-off edge at time t3 to time t4, switch 121 of gate drive circuit 101 is rendered non-conductive and switch 122 is rendered conductive, and thereby, the charges accumulated in gate terminal 4 of driven element 1 are discharged through the gate resistor, switch 122, and forward diode 108. As a result, gate terminal 4 of driven element 1 changes from a positive potential to a reference potential. During this time period, the signal at node F is at a low level, and thus, switch 203 of potential switching circuit 201 is non-conductive. Therefore, first electrode 109A of capacitor 109 is maintained at the same potential as reference potential V_{SS} via diode 108.

During a time period from the next time t4 to time t6, the signal at node F switches into a high level, and switch 203 of potential switching circuit 201 is rendered conductive. Thereby, second electrode 109B of capacitor 109 is connected to reference node 103 via switch 203. As a result, first electrode 109A of capacitor 109 is negatively biased, and gate terminal 4 of driven element 1 that is connected to first electrode 109A of capacitor 109 via switch 122 in the conductive state and the gate resistor is also negatively biased. In other words, the potential at gate terminal 4 changes from a reference potential to a negative potential. Note that diode 108 receives a voltage in the reverse direction, and thus, is rendered non-conductive. In this time period from time t4 to time t6 during which a negative bias is applied, the drive element of the counter arm is turned on to thereby prevent a false turn-on phenomenon from occurring in the self-arm.

During a time period from the next time t6 to the turn-on edge at time t7, the signal at node F switches into a low level, and switch 203 of potential switching circuit 201 is rendered non-conductive. Thereby, second electrode 109B of capacitor 109 is disconnected from reference node 103 and connected again to power supply node 102. Thus, first electrode 109A of capacitor 109 is connected to reference node 103 via forward diode 108. Gate terminal 4 of driven element 1 that is connected to first electrode 109A of capacitor 109 via switch 122 in the conductive state and the gate resistor also has a reference potential. The voltage change as described above is subsequently repeated.

### Effects of the First Embodiment

According to the configuration and the operation of gate drive circuit 101 described above, occurrence of a false turn-on phenomenon in driven element 1 can be prevented even when capacitor 109 having a minimum capacitance is used. The reason therefor will be hereinafter specifically described.

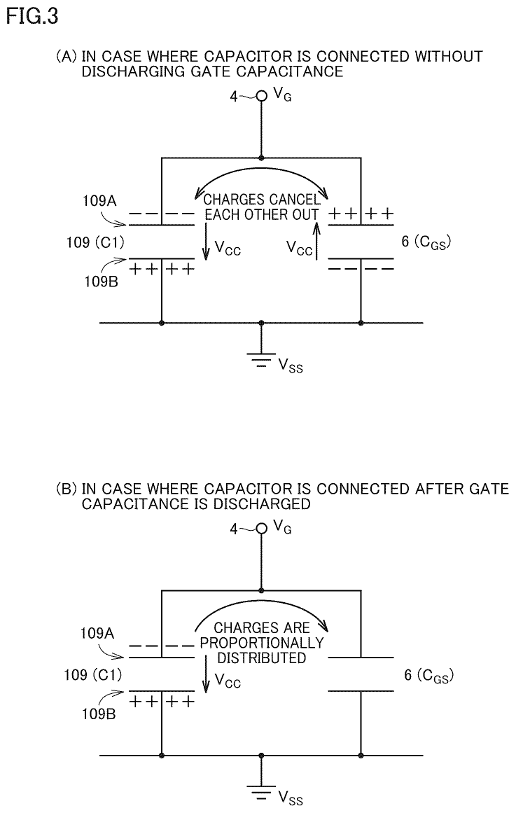

FIG. 3 is a schematic circuit diagram conceptually showing the charging status of capacitor 109 and the charging status of gate capacitance 6 immediately after second electrode 109B of capacitor 109 is connected to a reference potential.

FIG. 3(A) shows the charging statuses of capacitor 109 and gate capacitance 6 in a comparative example. In the case of the comparative example, capacitor 109 for negative bias generation is connected to gate capacitance 6 of driven element 1 immediately after driven element 1 is turned off. In other words, capacitor 109 for negative bias generation is connected to gate capacitance 6 at the same time when gate terminal 4 is disconnected from power supply node 102 in the state in which driven element 1 is in an ON state and positive charges are accumulated in gate terminal 4.

In this case, the negative charges accumulated in first electrode 109A of capacitor 109 for negative bias generation and the positive charges accumulated in gate terminal 4 cancel each other out. As a result, the potential at gate terminal 4 is not sufficiently lowered. In other words, the effect of the negative bias is reduced.

For example, it is assumed that a gate capacitance C_{GS} is equal to a capacitance C1 of capacitor 109. It is also assumed that each of gate capacitance 6 and capacitor 109 is charged with positive potential V_{CC} before gate capacitance 6 and capacitor 109 are connected to each other. In this case, due to connection of gate capacitance 6 and capacitor 109, the charges completely cancel each other out. As a result, after capacitor 109 for negative bias generation is connected, the gate potential becomes zero, i.e., becomes equal to reference potential V_{SS}, and does not become negative. In order to sufficiently apply a negative bias to gate terminal 4, capacitance C1 of capacitor 109 needs to be sufficiently increased, which causes a problem of an increase in circuit scale and an increase in cost.

FIG. 3(B) shows charging statuses of capacitor 109 and gate capacitance 6 in the present embodiment. In the present embodiment, the above-described disadvantage in the comparative example can be solved.

Specifically, as described above, gate terminal 4 is once connected to reference node 103 when driven element 1 is turned off. Thereby, the charges accumulated in gate capacitance 6 are discharged, so that the voltage at gate terminal 4 temporarily becomes zero. Then, capacitor 109 for negative bias generation is connected in reverse polarity between gate terminal 4 and reference node 103. This situation is shown in FIG. 3(B).

As shown in FIG. 3(B), capacitor 109 for negative bias generation is connected between gate terminal 4 and reference node 103 in the state in which the charges connected to gate capacitance 6 become zero. Thus, some of the negative charges accumulated in first electrode 109A of capacitor 109 move to gate terminal 4 while the remaining negative charges remain in first electrode 109A of capacitor 109. Therefore, unlike the comparative example in FIG. 3(A), the negative charges in first electrode 109A of capacitor 109 do not cancel out the positive charges in gate terminal 4. As a result, capacitance C1 of capacitor 109 for negative bias generation does not need to be increased.

In gate drive circuit 101 in the present embodiment as described above, the capacitance of capacitor 109 for negative bias generation can be smaller than that in the conventional case. The following describes how much capacitance C1 of capacitor 109 can be reduced.

In the following description, the gate capacitance of driven element 1 is defined as C_{GS}, the capacitance of the capacitor for negative bias generation is defined as C1, the gate power supply voltage is defined as V_{CC}, and the turn-on threshold value of driven element 1 is defined as V_{TH}. Further, V_{SURGE} denotes the peak value of the surge voltage occurring at the gate terminal of the self-arm when the counter arm is turned on, in the case where capacitor 109 for negative bias generation is not provided, i.e., in the case where a negative bias is not applied to gate terminal 4.

When peak value V_{SURGE} of the surge voltage occurring at the gate terminal of the self-arm at the time of turn-on of the counter arm exceeds turn-on threshold value V_{TH} of driven element 1 of the self-arm, a false turn-on phenomenon occurs in the self-arm. This may result in destruction of the driven element of the self-arm. Therefore, the negative bias should only be applied to gate terminal 4 such that peak value V_{SURGE} of the surge voltage becomes equal to or smaller than turn-on threshold value V_{TH}.

In the present embodiment, capacitor 109 for negative bias generation is connected to gate capacitance C_{GS} after gate capacitance C_{GS} is once discharged. As a result, charges Q1 accumulated in capacitor 109 for negative bias generation are proportionally distributed between capacitor 109 and gate capacitance Cos.

Assuming that the capacitance of capacitor 109 is defined as C1, charges Q1 are represented as follows.

Q1=C1×V_{CC} (1)

After capacitor 109 is connected to gate capacitance C_{GS}, the charges proportionally distributed to both capacitor 109 and gate capacitance C_{GS} shows a capacitance ratio between capacitance C1 and capacitance C_{GS}. Therefore, charges Q1^{R} remaining in capacitor 109 of capacitance C1 are represented as follows.

Q1^{R}=C1/(C1+C_{GS})×Q1=C1/(C1+C_{GS})×C1×V_{CC}=C1²/(C1+C_{GS})×V_{CC} (2)

Similarly, charges Q_{G}^{R} transferred from capacitor 109 to gate capacitance C_{GS} are represented as follows.

Q_{G}^{R}=C_{GS}/(C1+C_{GS})×Q1=C_{GS}/(C1+C_{GS})×C1×V_{CC}=C1×C_{GS}/(C1+C_{GS})×V_{CC} (3)

Therefore, after capacitor 109 is connected to gate capacitance C_{GS}, an absolute value |V_{C1}^{R}| of the potential difference across capacitor 109 is represented as follows.

|V_{C1}^{R}|=Q1^{R}/C1=C1²/(C1+C_{GS})×V_{CC}/C1=C1/(C1+C_{GS})×V_{CC} (4)

Similarly, after capacitor 109 is connected to gate capacitance C_{GS}, an absolute value |V_{GS}^{R}| of the potential difference across gate capacitance C_{GS} is represented as follows.

|V_{GS}^{R}|=Q_{G}^{R}/C_{GS}=C1×C_{GS}/(C1+C_{GS})×V_{CC}/C_{GS}=C1/(C1+C_{GS})×V_{CC} (5)

Absolute value |V_{C1}^{R}| of the voltage of capacitor 109 is naturally equal to absolute value |V_{GS}^{R}| of the voltage of gate capacitance C_{GS}. This voltage acts as a negative bias.

In order to prevent a false turn-on phenomenon in driven element 1, the peak of the surge voltage should only be lowered by the negative bias to be equal to or lower than gate threshold voltage V_{TH}. In other words, the absolute value of the minimum necessary voltage as a negative bias is equal to the difference between gate threshold voltage V_{TH} of the driven element and surge peak V_{SURGE} of the gate voltage in the self-arm at the time when the counter arm is turned on without applying a negative bias. In other words, since absolute value |V_{C1}^{R}| of the potential difference across capacitor 109 should only be equal to or greater than the above-mentioned difference, the following is satisfied.

V_{SURGE}−V_{TH}≤|V_{GS}^{R}|=C1/(C1+C_{GS})×V_{CC} (6)

By modifying the above-mentioned equation (6), the following is eventually obtained.

(V_{SURGE}−V_{TH})×(C1+C_{GS})≤C1×V_{CC}(V_{SURGE}−V_{TH})×C1+(V_{SURGE}−V_{TH})×C_{GS}≤C1×V_{CC}(V_{SURGE}−V_{TH})×C1−C1×V_{CC}≤−(V_{SURGE}−V_{TH})×C_{GS}(V_{SURGE}−V_{TH}−V_{CC})×C1≤−(V_{SURGE}−V_{TH})×C_{GS}−(V_{SURGE}−V_{TH}−V_{CC})×C1≥(V_{SURGE}−V_{TH})×C_{GS}C1≥(V_{SURGE}−V_{TH})/(V_{CC}−(V_{SURGE}−V_{TH}))×C_{GS} (7)

Thus, the right side of the above-mentioned expression (7) shows a lower limit value of capacitance C1 of capacitor 109. Capacitance C1 should only be set not to fall below this lower limit value.

This lower limit value of capacitance C1 cannot be achieved by the prior art. As in the present embodiment, this lower limit value can be achieved only by connecting capacitor 109 for negative bias generation to gate capacitance C_{GS} after gate capacitance C_{GS} is once discharged after driven element 1 is turned off.

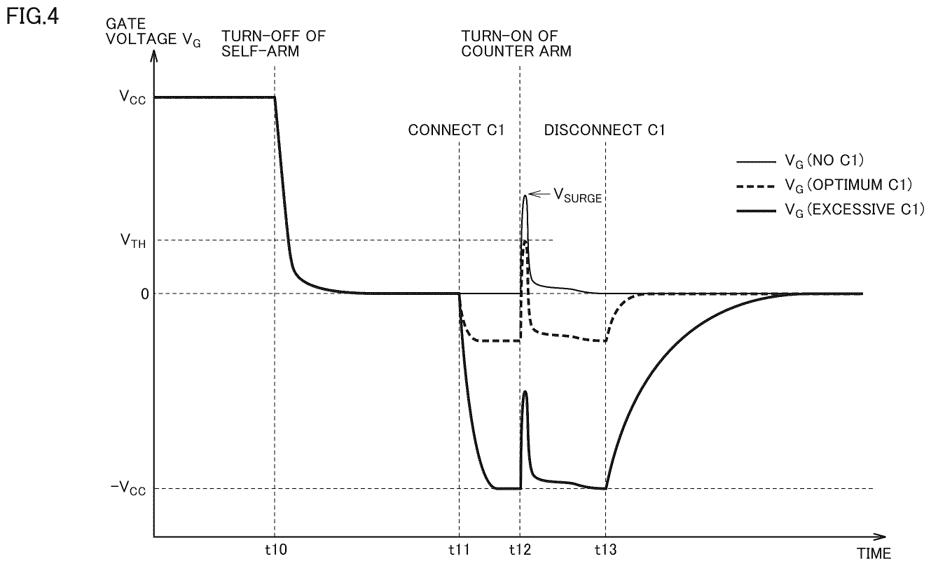

FIG. 4 is a diagram showing a temporal change in an actual gate voltage after the driven element is turned off. In FIG. 4, the waveform represented by a thin solid line indicates a temporal change in the gate voltage when the negative bias is not used, i.e., when capacitor 109 for negative bias generation is not provided.

Specifically, after the self-arm is turned off at time t10, dead time subsequently elapses, and then, the counter arm is turned on at time t12. When the counter arm is turned on, the gate voltage in the self-arm is raised and the voltage rises to surge peak V_{SURGE}. In the case of the waveform represented by the thin solid line in FIG. 4, surge peak V_{SURGE} exceeds gate threshold voltage V_{TH}, and thus, the element may be broken by a false turn-on phenomenon.

Thus, during a time period from time t11 to time t13 including time t12 at which the counter arm is turned on, capacitor 109 for negative bias generation is connected to gate capacitance C_{GS}, and thereby, the negative bias is applied to gate terminal 4. In this case, it is important not to unnecessarily increase capacitance C1 of capacitor 109.

For example, if capacitance C1 of capacitor 109 is extremely increased, gate voltage V_{G} can be lowered to be close to an inverted voltage—V_{CC} of power supply voltage V_{CC} of gate drive circuit 101 as indicated by the waveform represented by a thick solid line in FIG. 4. However, such a large negative bias is not necessary. This is because the effect of preventing a false turn-on phenomenon remains unchanged even when the peak of the surge voltage is significantly lower than gate threshold voltage V_{TH}. Further, unnecessarily increasing capacitance C1 of capacitor 109 also causes problems of an increase in circuit scale and an increase in cost. Further, it is known that, in the case where the driven element is a silicon carbide MOSFET (SiC-MOSFET), extremely high negative bias voltage gives unnecessary stress to the gate oxide film of the driven element to thereby lower the gate threshold voltage. Thus, the magnitude of the negative bias should be minimized. In the present embodiment, the minimum limit value of the negative bias voltage is clarified as described above, and the circuit configuration necessary for achieving the value is clarified.

Although the upper limit of capacitance C1 is not limited in terms of operation, an unnecessarily large capacitance leads to an increase in circuit scale and an increase in cost as described above, and adversely affects the gate oxide film. It is conceivable that a decrease in gate threshold voltage V_{TH} may raise a possibility that capacitance C1 needs to be increased to some extent. Gate threshold voltage V_{TH} may fall from its original value due to various factors, in which case capacitance C1 needs to be increased accordingly. However, even in consideration of the worst case, gate threshold voltage V_{TH} is a positive value and is larger than 0 V.

On condition that V_{TH}=0 in the equation (6), the following is obtained.

V_{SURGE}≤C1/(C1+C_{GS})×V_{CC} (8)

By modifying the above-mentioned expression (8), the following is obtained.

C1≥V_{SURGE}/(V_{CC}−V_{SURGE})×C_{GS} (9)

The right side of the expression (9) is capacitance C1 of capacitor 109 that is necessary in the worst case (i.e., in the case where V_{TH}=0), and capacitance C1 does not need to be increased any more. Therefore, the right side of the expression (9) shows an upper limit of capacitance C1. In other words, the following is obtained as an expression for specifying the upper limit of capacitance C1.

C1≤V_{SURGE}/(V_{CC}−V_{SURGE})×C_{GS} (10)

By combining the expression (10) with the expression (7), the following is obtained.

V_{SURGE}/(V_{CC}−V_{SURGE})×C_{GS}≥C1≥(V_{SURGE}−V_{TH})/(V_{CC}−(V_{SURGE}−V_{TH}))×C_{GS} (11)

The above-mentioned expression (11) specifies the upper limit and the lower limit of capacitance C1 of capacitor 109.

The waveform represented by a dotted line in FIG. 4 shows a temporal change in gate voltage V_{G} that occurs when the capacitance of capacitor 109 for negative bias generation is optimized.

The negative bias is minimized, and the surge peak of the gate voltage of the self-arm at the time of turn-on of the counter arm does not exceed V_{TH}.

Further, in the present embodiment, since the negative bias is applied after the gate voltage is once set at zero (0) at the time of turn-off of the self-arm, the time period during which the negative bias is applied can also be minimized. As described above, in the case of a SiC-MOSFET, applying a negative bias to a gate gives stress to a gate oxide film. Thus, it is preferable that not only the magnitude of the negative bias is as small as possible but also the time period of applying the negative bias is as short as possible. According to the present embodiment, the time period during which the negative bias is applied to the gate can be limited to a short time period including the moment at which the counter arm is turned on.

The time width during which the negative bias is applied can be controlled by adjusting the time constant of the low-pass filter for generating the first signal in FIG. 1, i.e., the size of resistor 303 and/or capacitor 304. The temporal position of the moment at which the negative bias is started to be applied can be controlled by adjusting the time constant of the low-pass filter by which the first signal is delayed, i.e., the size of resistor 307 and/or capacitor 308. By controlling the above, the time period during which the negative bias is applied can be minimized. This is also an effect that could not be achieved by the prior art.

### Reason Why Unidirectional RC Filter is Necessary

The following describes the reason why the unidirectional RC filter is used in first delay circuit 320 of signal generation circuit 301.

In the present embodiment, first delay circuit 320 is configured as a unidirectional RC filter that delays only the turn-off edge of gate drive signal GDS without delaying the turn-on edge thereof. Thereby, even when the ON-pulse width of gate drive signal GDS is extremely short, the negative bias can be reliably applied to gate terminal 4 of driven element 1. Hereinafter, specific examples will be described.

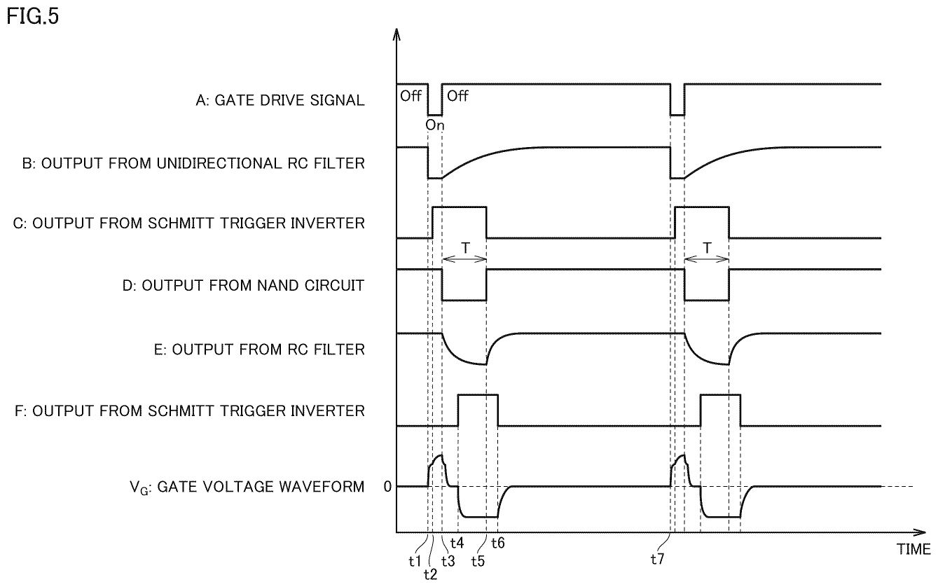

FIG. 5 is a timing chart showing the operation of gate drive circuit 101 in FIG. 1 when the ON-pulse width of gate drive signal GDS is extremely short. The timing chart in FIG. 5 corresponds to the timing chart in FIG. 2, and shows the signal waveforms at nodes A to F in FIG. 1 and the waveform of gate voltage V_{G} of driven element 1 in FIG. 1. Time t1 to time t7 in FIG. 5 respectively correspond to time t1 to time t7 in FIG. 2.

As shown in FIG. 5, the ON-pulse width (i.e., from time t1 to time t3) of gate drive signal GDS (i.e., the signal at node A) is very short. Even in such a case, the negative bias can be applied to gate terminal 4 between time t4 and time t6 after the turn-off edge at time t3.

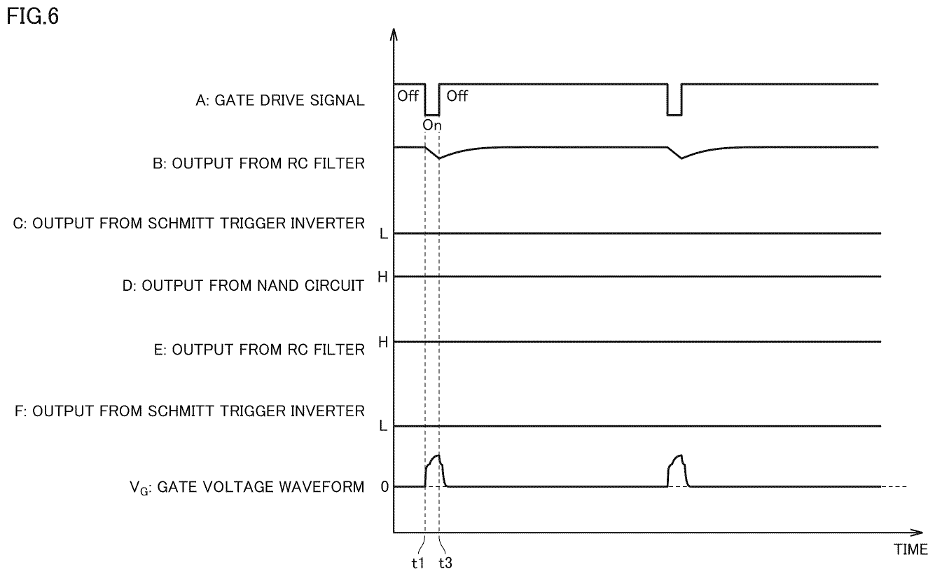

FIG. 6 is a timing chart showing an operation of a modification of gate drive circuit 101 in FIG. 1. In the gate drive circuit in the modification, first delay circuit 320 of signal generation circuit 301 in FIG. 1 is configured not to include diode 302.

Thus, the modified first delay circuit is a bidirectional delay circuit that delays both the turn-on edge and the turn-off edge.

The timing chart in FIG. 6 shows the signal waveforms at nodes A to F in FIG. 1 and the waveform of gate voltage V_{G} of driven element 1 in FIG. 1 in the case of the modification as described above. In FIG. 6, the waveform of gate drive signal GDS (the signal at node A) is the same as that in FIG. 5.

The waveform of the signal at node B (i.e., the output signal from the modified first delay circuit) starts to slowly decrease at the turn-on edge of gate drive signal GDS at time t1. However, since the ON-pulse width of gate drive signal GDS is very short, the signal at node B is pulled back slowly in the direction toward the original high level immediately at the turn-off edge at time t3.

As a result, since the signal at node B does not exceed the operation threshold value of Schmitt trigger inverter 305 of first delay circuit 320, Schmitt trigger inverter 305 does not work. Thereby, the modified signal generation circuit cannot detect the turn-off edge of gate drive signal GDS. Thus, the signal at node C does not change and remains at a low (L) level, and accordingly, the signals at nodes D and E do not change and remain at a high (H) level, with the result that the signal at node F does not change and remains at a low (L) level. Finally, a negative bias is not applied to gate terminal 4. This causes a false turn-on phenomenon.

In order to avoid such a problem, it is necessary to delay only the turn-off edge of gate drive signal GDS without delaying the turn-on edge thereof by using a unidirectional filter in first delay circuit 320 of signal generation circuit 301.

### Second Embodiment.

### Configuration Of Gate Drive Circuit

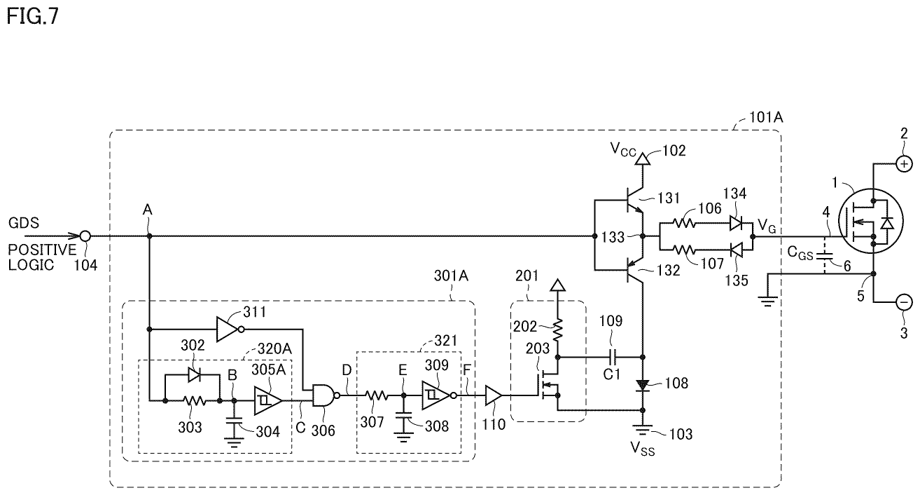

FIG. 7 is a circuit diagram showing a configuration example of a gate drive circuit 101A according to the second embodiment. Gate drive circuit 101A in FIG. 7 is a modification of gate drive circuit 101 in FIG. 1.

Specifically, gate drive circuit 101A in FIG. 7 is different from gate drive circuit 101 in FIG. 1 in that an NPN transistor 131 (the first switch) is used instead of switch 121 constituted of a P-channel MOSFET, and a PNP transistor 132 (the second switch) is used instead of switch 122 constituted of an N-channel MOSFET.

NPN transistor 131 and PNP transistor 132 have respective base terminals connected to signal input terminal 104. A point of connection 133 between NPN transistor 131 and PNP transistor 132 is connected to gate terminal 4 of driven element 1 via gate resistor 106 and a forward diode for turn-on, and is also connected to gate terminal 4 of driven element 1 via gate resistor 107 and a backward diode for turn-off.

NPN transistor 131 and PNP transistor 132 constitute an emitter follower circuit, in which the logical value of the input signal matches the logical value of the output signal. On the other hand, in the CMOS circuit constituted of switches 121 and 122 in FIG. 1, the logical value of the input signal and the logical value of the output signal are inverted. Thus, gate drive signal GDS is input in a negative logic to gate drive circuit 101 in FIG. 1, whereas gate drive signal GDS is input in a positive logic to gate drive circuit 101 in FIG. 7.

Due to gate drive signal GDS input in a positive logic, a failure occurs for some reason in the circuit that generates gate drive signal GDS. Thus, even if the input signal of gate drive circuit 101 remains at a reference potential for a long time period, driven element 1 is not kept in an ON state for a long time period. Therefore, there is an advantage that a short-circuit accident or the like is less likely to occur.

Due to gate drive signal GDS input in a positive logic, signal generation circuit 301 in FIG. 1 is modified to a signal generation circuit 301A in FIG. 7. Specifically, signal generation circuit 301A in FIG. 7 includes a first delay circuit 320A, a NOT circuit 311, logical operation circuit 306, second delay circuit 321, diode 108, capacitor 109, and non-inverting buffer 110. Among these components, second delay circuit 321, diode 108, capacitor 109, and non-inverting buffer 110 are the same in terms of configuration and connection as those in signal generation circuit 301 in FIG. 1, and thus, the same or corresponding portions are denoted by the same reference characters, and the description thereof will not be repeated.

Gate drive signal GDS in a positive logic is input to first delay circuit 320A. First delay circuit 320A generates a first delay signal by delaying the turn-off edge (i.e., the falling edge) of the input gate drive signal GDS in a positive logic without delaying the turn-on edge (i.e., the rising edge) thereof. First delay circuit 320A outputs the generated first delay signal.

More specifically, as shown in FIG. 7, first delay circuit 320A includes: a low-pass filter (also referred to as an RC filter) constituted of resistor 303 and capacitor 304; diode 302; and a Schmitt trigger buffer 305A. Resistor 303 and capacitor 304 are connected in this order in series between signal input terminal 104 and reference node 103. Diode 302 is connected in parallel with resistor 303 in the direction reverse to that in FIG. 1. In other words, the cathode terminal of diode 302 is connected to connection node B between resistor 303 and capacitor 304. Thereby, the RC filter functions as a unidirectional RC filter that delays only the falling edge of gate drive signal GDS. The signal that has passed through the RC filter is input to Schmitt trigger buffer 305A. Schmitt trigger buffer 305A shapes the input signal but does not invert the logical value thereof.

Logical operation circuit 306 computes a logical product of: the first delay signal output from first delay circuit 320; and a signal obtained by inverting gate drive signal GDS by NOT circuit 311. In the example in FIG. 1, since a NAND circuit is used as logical operation circuit 306, logical operation circuit 306 inverts the operation result of the logical product and outputs the inverted result. Note that logical operation circuit 306 may calculate the logical sum of the inverted signal of the first delay signal and gate drive signal GDS, in which case the same logical operation result is obtained.

Since other configurations in FIG. 7 are the same as those in FIG. 1, the same or corresponding portions are denoted by the same reference characters, and the description thereof will not be repeated.

### Operation of Gate Drive Circuit

The following describes the operation of gate drive circuit 101A in FIG. 7, in particular, the operation of signal generation circuit 301A.

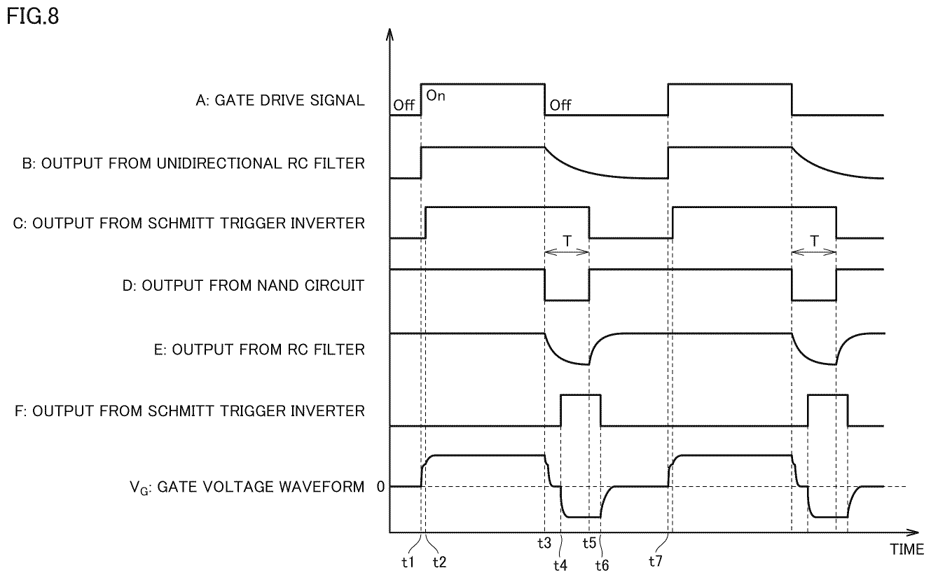

FIG. 8 is a timing chart showing the operation of gate drive circuit 101A in FIG. 7. The timing chart in FIG. 8 corresponds to the timing chart in FIG. 2, and shows the signal waveforms at nodes A to F and the waveform of gate voltage V_{G} of driven element 1 in FIG. 8. Hereinafter, differences from FIG. 2 will be described.

The signal at node A is gate drive signal GDS, and is input to the base terminal of NPN transistor 131 and the base terminal of PNP transistor 132.

When gate drive signal GDS is at a low level, PNP transistor 132 turns into an ON state, so that gate terminal 4 of driven element 1 is connected to reference node 103. This brings driven element 1 into an OFF state. On the other hand, when gate drive signal GDS is at a high level, NPN transistor 131 turns into an ON state, so that gate terminal 4 of driven element 1 is connected to power supply node 102. This brings driven element 1 into an ON state.

Therefore, gate drive signal GDS is a positive logic. Time t1 at which gate drive signal GDS switches from a low level to a high level (i.e., the rising edge of gate drive signal GDS) corresponds to a turn-on edge. Time t3 at which gate drive signal GDS switches from a high level to a low level (i.e., the falling edge of gate drive signal GDS) corresponds to a turn-off edge.

The signal at node B indicates the signal output from the unidirectional RC filter of first delay circuit 320A when the signal at node A (i.e., gate drive signal GDS) is input to the unidirectional RC filter. In the unidirectional RC filter of first delay circuit 320A, when the input signal rises, the diode is rendered conductive, so that the low-pass filter is disabled. On the other hand, when the input signal falls, the diode is disconnected, so that the low-pass filter is enabled.

Specifically, at time t1 corresponding to the rising edge (i.e., the turn-on edge) of gate drive signal GDS, the output signal from the unidirectional RC filter (i.e., the signal at node B) rapidly rises. On the other hand, at time t3 corresponding to the falling edge (i.e., the turn-off edge) of gate drive signal GDS, the output signal from the unidirectional RC filter (i.e., the signal at node B) gently falls.

The signal at node C indicates the signal output from Schmitt trigger buffer 305A when the signal at node B (i.e., the output signal from the unidirectional RC filter) is input to Schmitt trigger buffer 305A. When a signal in which only the falling edge is obtuse like the signal at node B in FIG. 8 is input to Schmitt trigger buffer 305A, Schmitt trigger buffer 305A outputs a signal in which only the falling edge of the input signal is significantly delayed.

The signal at node D indicates an output signal from the NAND circuit serving as logical operation circuit 306. As shown in FIG. 8, NAND circuit 306 outputs a signal obtained by inverting a logical product of: the signal obtained by inverting the signal at node A (i.e., gate drive signal GDS) by NOT circuit 311; and the signal at node C (i.e., the output signal from Schmitt trigger buffer 305A).

In the case in FIG. 8, the logical product of the inverted signal of the signal at node A and the signal at node C is true only during certain time period T from the turn-off edge (for example, from time t3 to time t5 in FIG. 2), and is false during other time periods. Therefore, the signal at node D (i.e., the output signal from NAND circuit 306) has a reference potential only during certain time period T from the turn-off edge, and has a positive potential during other time periods. The signal at node D is the same as the signal in FIG. 2 in the first embodiment.

Since the signals at nodes E and F and gate voltage waveform V_{G} are the same as those in FIG. 2, the description thereof will not be repeated.

### Effects of the Second Embodiment

As described above, when gate drive signal GDS is a positive logic, the logical product of: the first delay signal obtained by delaying only the turn-off edge of gate drive signal GDS without delaying the turn-on edge thereof; and the inverted signal of the original gate drive signal GDS is computed. Then, both the rising edge and the falling edge of the operation result of this logical product are delayed to thereby generate a control signal to be output to potential switching circuit 201 for enabling the negative bias. According to the configuration in the second embodiment described above, a false turn-on phenomenon can be prevented by applying a minimum necessary negative bias to gate terminal 4 of driven element 1, as in the case of the first embodiment.

### Third Embodiment.

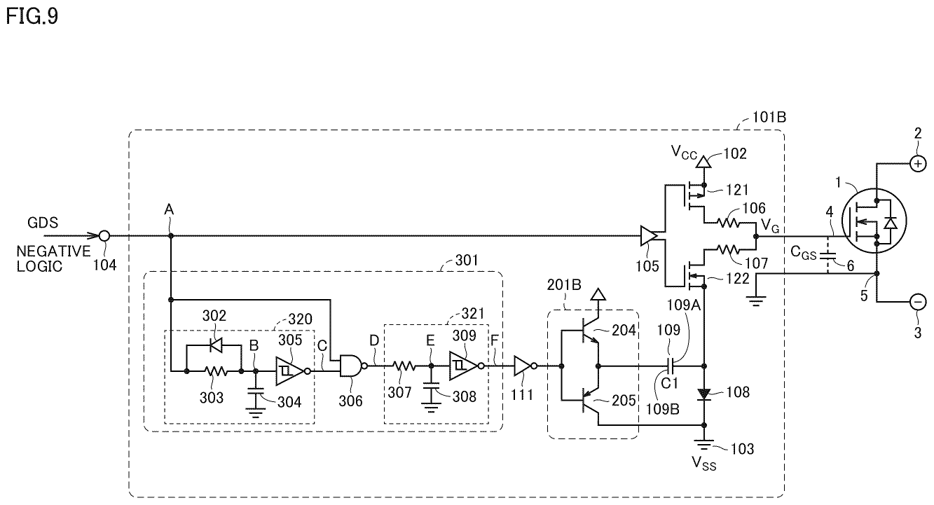

FIG. 9 is a circuit diagram showing a configuration example of a gate drive circuit 101B in the third embodiment. In gate drive circuit 101B in FIG. 7, a potential switching circuit 201B is different in configuration from potential switching circuit 201 in FIG. 1.

Specifically, potential switching circuit 201 in FIG. 1 is of an open drain type in which pull-up resistor 202 and switch 203 that is constituted of an N-channel MOSFET are used. On the other hand, potential switching circuit 201B in FIG. 9 is constituted of an emitter follower circuit formed using an NPN transistor 204 (the third switch) and a PNP transistor 205 (the fourth switch). Further, since the above-mentioned emitter follower circuit operates in a positive logic unlike the open drain circuit in FIG. 1, an inverting buffer 111 is provided instead of non-inverting buffer 110 in FIG. 1.

More specifically, NPN transistor 204 and PNP transistor 205 are connected in this order in series between power supply node 102 and reference node 103. NPN transistor 204 and PNP transistor 205 have respective base terminals output to the output terminal of inverting buffer 111. A point of connection between NPN transistor 204 and PNP transistor 205 is connected to second electrode 109B of capacitor 109.

When the control signal output from inverting buffer 111 is at a low level (enabled), PNP transistor 205 turns into an ON state and NPN transistor 204 turns into an OFF state, so that the negative bias is enabled. When the control signal output from inverting buffer 111 is at a high level (disabled), PNP transistor 205 turns into an OFF state and NPN transistor 204 turns into an ON state, so that the negative bias is disabled and capacitor 109 is charged.

Since other configurations in FIG. 9 are the same as those in FIG. 1, the same or corresponding portions are denoted by the same reference characters, and the description thereof will not be repeated.

In the case of potential switching circuit 201 shown in FIG. 1, when switch 203 is in an ON state in order to apply a negative bias to gate terminal 4, power supply node 102 is connected to reference node 103 via pull-up resistor 202. This causes a problem that power consumption increases.

On the other hand, in the case of potential switching circuit 201B shown in FIG. 9, when PNP transistor 205 is in an ON state in order to apply a negative bias to gate terminal 4, power supply node 102 is disconnected from other circuits by NPN transistor 204 in an OFF state. Therefore, gate drive circuit 101B in the third embodiment has an advantage that power consumption can be reduced as compared with gate drive circuit 101 in the first embodiment.

### Fourth Embodiment

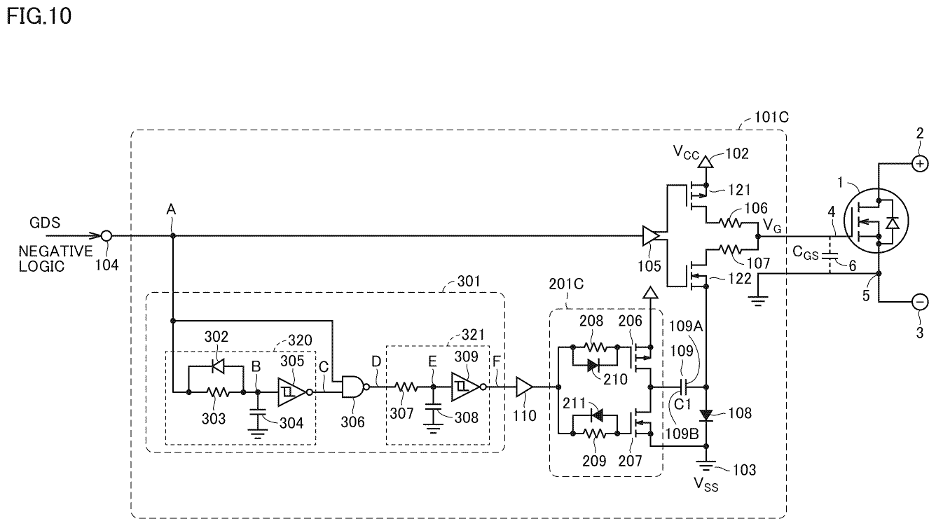

FIG. 10 is a circuit diagram showing a configuration example of a gate drive circuit 101C in the fourth embodiment. In gate drive circuit 101C in FIG. 10, a potential switching circuit 201C is different in configuration from both potential switching circuit 201 in FIG. 1 and potential switching circuit 201B in FIG. 9.

Specifically, potential switching circuit 201 in FIG. 1 is of an open drain type in which pull-up resistor 202 and switch 203 that is constituted of an N-channel MOSFET are used. Potential switching circuit 201B in FIG. 9 is constituted of an emitter follower circuit formed using NPN transistor 204 and PNP transistor 205. On the other hand, potential switching circuit 201C in FIG. 10 is constituted of a CMOS push-pull circuit formed using a P-channel MOSFET 206 (the third switch) and an N-channel MOSFET 207 (the fourth switch). The CMOS push-pull circuit operates in a negative logic similarly to the open drain circuit.

More specifically, P-channel MOSFET 206 and N-channel MOSFET 207 are connected in this order in series between power supply node 102 and reference node 103. A point of connection between P-channel MOSFET 206 and N-channel MOSFET 207 is connected to second electrode 109B of capacitor 109. A resistor 208 and a diode 210 are connected in parallel with each other between the gate terminal of P-channel MOSFET 206 and the output terminal of non-inverting buffer 110. The cathode of diode 210 is connected to the gate terminal of P-channel MOSFET 206, and the anode of diode 210 is connected to the output terminal of non-inverting buffer 110. A resistor 209 and a diode 211 are connected in parallel with each other between the gate terminal of N-channel MOSFET 207 and the output terminal of non-inverting buffer 110. The cathode of diode 211 is connected to the output terminal of non-inverting buffer 110, and the anode of diode 211 is connected to the gate terminal of N-channel MOSFET 207.

When the control signal output from non-inverting buffer 110 is at a high level (enabled), N-channel MOSFET 207 turns into an ON state and P-channel MOSFET 206 turns into an OFF state, so that the negative bias is enabled. When the control signal output from non-inverting buffer 110 is at a low level (disabled), N-channel MOSFET 207 turns into an OFF state and P-channel MOSFET 206 turns into an ON state, so that the negative bias is disabled and capacitor 109 is charged.

Since other configurations in FIG. 10 are the same as those in FIG. 1, the same or corresponding portions are denoted by the same reference characters, and the description thereof will not be repeated.

In the case of potential switching circuit 201 shown in FIG. 1, when switch 203 is in an ON state in order to apply a negative bias to gate terminal 4, power supply node 102 is connected to reference node 103 via pull-up resistor 202. This causes a problem that power consumption increases. Further, in the case of the emitter follower circuit used in potential switching circuit 201B in FIG. 9, there is a problem that power is consumed by a base current at the time of switching. On the other hand, in the case of the push-pull circuit used in potential switching circuit 201C in FIG. 10, the above-mentioned problems can be avoided, and there is an advantage that power consumption can be reduced as compared with the cases in the first to third embodiments.

### Summary of the Embodiments

The following describes a summary of the above. Specifically, according to gate drive circuits 101, 101A, 101B, and 101C in the first to fourth embodiments, a negative bias necessary and sufficient to prevent a false turn-on phenomenon can be applied to the gate of driven element 1 by using a capacitor having a minimum necessary capacitance. Further, gate drive circuits 101, 101A, 101B, and 101C in the first to fourth embodiments do not require a negative power supply, do not require special processing for a gate drive signal, and also do not require a separate signal for enabling a negative bias. In other words, the gate drive circuit in each of the first to fourth embodiments can be directly replaced, for installation, with a conventional simple gate drive circuit with no negative bias. This means that it can be easily attached to a device in operation, and thereby can easily be additionally provided with a function of preventing a false turn-on phenomenon. Therefore, the gate drive circuit in each of the first to fourth embodiments has a remarkable characteristic of having a wide application range.

### Modifications of the Embodiments

The types of the semiconductor elements adopted in the above description of the respective embodiments are not limited thereto, and may be replaced with other types of semiconductor elements. For example, driven element 1 is not limited to a MOSFET but may be an IGBT. In the case of an IGBT, the drain terminal of the MOSFET is replaced with a collector terminal, and the source terminal of the MOSFET is replaced with an emitter terminal. Potential switching circuit 201 in each of the first and second embodiments may be not only an open drain circuit but also an open collector circuit. Each of potential switching circuits 201B and 201C described in the third and fourth embodiments can also be combined with the emitter follower circuit constituted of NPN transistor 131 and PNP transistor 132 described in the second embodiment.

It should be understood that the embodiments disclosed herein are illustrative and non-restrictive in every respect. The scope of the present application is defined by the terms of the claims, rather than the description above, and is intended to include any modifications within the scope and meaning equivalent to the terms of the claims.

### REFERENCE SIGNS LIST

1 driven element, 2 drain terminal, 3 source terminal, 4 gate terminal, 5 source reference terminal, 6 gate capacitance, 101, 101A, 101B, 101C gate drive circuit, 102 power supply node, 103 reference node, 104 signal input terminal, 105, 110 non-inverting buffer, 106, 107 gate resistor, 108, 210, 211, 302 diode, 109, 304, 308 capacitor, 109A first electrode, 109B second electrode, 111 inverting buffer, 121, 122, 203 switch, 131, 132, 204, 205 bipolar transistor, 133 point of connection, 201, 201B, 201C potential switching circuit, 202 pull-up resistor, 206, 207 MOSFET, 208, 209, 303, 307 resistor, 301, 301A signal generation circuit, 305, 309 Schmitt trigger inverter, 305A Schmitt trigger buffer, 306 logical operation circuit (NAND circuit), 311 NOT circuit, 320, 320A first delay circuit, 321 second delay circuit.

1. A gate drive circuit to drive a driven element based on a gate drive signal, the gate drive circuit comprising:
a first switch connected between a power supply node to which a positive potential is applied and a gate terminal of the driven element to turn the driven element into an ON state by being rendered conductive when the gate drive signal has a first logical value;
a second switch connected between a reference node to which a reference potential is applied and the gate terminal of the driven element to turn the driven element into an OFF state by being rendered conductive when the gate drive signal has a second logical value;
a diode connected between the second switch and the reference node such that the reference node is located on a cathode side;
a capacitor having a first electrode connected to a connection node between the second switch and the diode;
a potential switching circuit to apply the reference potential to a second electrode of the capacitor when a control signal is enabled, and to apply the positive potential to the second electrode of the capacitor when the control signal is disabled; and
a signal generation circuit to generate the control signal based on the gate drive signal, wherein
the signal generation circuit
enables the control signal after the gate drive signal switches from the first logical value to the second logical value and charges in the gate terminal of the driven element are subsequently discharged, and
disables the control signal before the gate drive signal switches from the second logical value to the first logical value.

2. The gate drive circuit according to claim 1, wherein the signal generation circuit includes:
a first delay circuit to generate a first delay signal by delaying a turn-off edge at which the gate drive signal switches from the first logical value to the second logical value and not delaying a turn-on edge at which the gate drive signal switches from the second logical value to the first logical value;
a logical operation circuit to perform a logical operation using the first delay signal and the gate drive signal; and
a second delay circuit to generate the control signal or an inverted signal of the control signal by delaying an operation result of the logical operation circuit.

3. The gate drive circuit according to claim 2, wherein
the first logical value is at a low level, and the second logical value is at a high level, and
the logical operation of the logical operation circuit includes:
a logical product of an inverted signal of the first delay signal and the gate drive signal; or
a logical sum of the first delay signal and an inverted signal of the gate drive signal.

4. The gate drive circuit according to claim 2, wherein
the first logical value is at a high level, and the second logical value is at a low level, and
the logical operation of the logical operation circuit includes:
a logical product of the first delay signal and an inverted signal of the gate drive signal; or
a logical sum of an inverted signal of the first delay signal and the gate drive signal.

5. The gate drive circuit according to claim 1, wherein
the potential switching circuit includes:
a resistor connected between the power supply node and the second electrode of the capacitor; and
a third switch connected between the second electrode of the capacitor and the reference node, and
the third switch turns into an ON state when the control signal is enabled and turns into an OFF state when the control signal is disabled.

6. The gate drive circuit according to claim 1, wherein
the potential switching circuit includes:
a third switch connected between the power supply node and the second electrode of the capacitor; and
a fourth switch connected between the second electrode of the capacitor and the reference node,
the third switch turns into an OFF state when the control signal is enabled and turns into an ON state when the control signal is disabled, and
the fourth switch turns into an ON state when the control signal is enabled and turns into an OFF state when the control signal is disabled.

7. The gate drive circuit according to claim 1, wherein
a self-arm constituted by the driven element is connected in series to a counter arm constituted by an additional drive element, and
a time period during which the control signal is enabled includes a timing at which the drive element of the counter arm is turned on.

8. The gate drive circuit according to claim 7, wherein assuming that
a potential difference between the positive potential and the reference potential is defined as V_{CC},
a gate capacitance of the driven element is defined as C_{GS},
a turn-on threshold value of the driven element is defined as V_{TH}, and
a peak value of a surge voltage occurring when the drive element of the counter arm is turned on in a case where the capacitor is not provided is defined as V_{SURGE},
a lower limit value of a capacitance of the capacitor is as follows:
(V_{SURGE}−V_{TH})/(V_{CC}−(V_{SURGE}−V_{TH}))×C_{GS}, and
an upper limit value of the capacitance of the capacitor is as follows:
V_{SURGE}/(V_{CC}−V_{SURGE})×C_{GS}.
